(19) United States
(12) Patent Application Publication
(10) Pub. No.: US 2005/0170650 A1
(43) Pub. Date: Aug. 4, 2005

(54) Electroless palladium nitrate activation prior to cobalt-alloy deposition

(76) Inventors: Hongbin Fang, Mountain View, CA (US); Ramin Emami, San Jose, CA (US); Timothy Weidman, Sunnyvale, CA (US); Arulkumar Shanmugasundram, Sunnyvale, CA (US); Fang Mei, Foster City, CA (US)

Correspondence Address: MOSER, PATTERSON & SHERIDAN, LLP;APPLIED MATERIALS, INC., 3040 POST OAK BOULEVARD, SUITE 1500, HOUSTON, TX, 77056, US

(21) Appl. No.: 10/970,354

(22) Filed: Oct. 21, 2004

Related U.S. Application Data
(60) Provisional application No. 60/539,544, filed on Jan. 26, 2004.

(51) Int. Cl. H01L 21/302; H01L 21/461

(52) U.S. Cl. 438/689

(57) ABSTRACT

In one embodiment, a method for activating a metal layer prior to depositing a cobalt-containing capping layer is provided which includes exposing the metal layer to an electroless activation solution to deposit a palladium layer on the metal layer and depositing the cobalt-containing capping layer on the palladium layer. The electroless activation solution contains palladium nitrate at a concentration in a range from about 0.01 mM to about 1.0 mM, nitric acid at a concentration in a range from about 0.01 mM to about 3.0 mM and water. In another embodiment, the electroless activation solution contains palladium nitrate at a concentration in a range from about 0.01 mM to about 1.0 mM, methanesulfonic acid at a concentration in a range from about 0.01 mM to about 3.0 mM and water.

### CROSS-REFERENCE TO RELATED APPLICATIONS

This application claims benefit of U.S. Provisional Patent Application Ser. No. 60/539,544, filed Jan. 26, 2004, which is herein incorporated by reference.

### BACKGROUND OF THE INVENTION

1. Field of the Invention

Embodiments of the invention generally relate to methods for depositing capping layers within a feature, formed as part of an electronic device, and more particularly to methods for depositing an activation layer on a conductive surface prior to depositing a capping layer.

2. Description of the Related Art

Recent improvements in circuitry of ultra-large scale integration (ULSI) on substrates indicate that future generations of semiconductor devices will require multi-level metallization with smaller geometric dimensions. The multilevel interconnects that lie at the heart of this technology require planarization of interconnect features formed in high aspect ratio features, including contacts, vias, lines and other features. Reliable formation of these interconnect features is very important to the success of ULSI and to the continued effort to increase circuit density and quality on individual substrates and dies as features continually decrease in size.

Copper and its alloys have become the metals of choice for sub-micron interconnect technology because copper has a lower resistivity than aluminum, (1.67 μΩ-cm compared to 3.1 μΩ-cm for aluminum at room temperature), a higher current carrying capacity and significantly higher electromigration resistance. These characteristics are important for supporting the higher current densities experienced at high levels of integration and increased device speed. Further, copper has a good thermal conductor and is available in a highly pure state.

However, copper has a couple of negative characteristics which must be dealt with to assure that the devices mode suing copper, meet the desired device performance characteristic and achieves a repeatable result. The first negative characteristic is the fact that copper diffuses rapidly through silicon, silicon dioxide and most dielectric materials on a substrate. Therefore, a barrier layer is needed to encapsulate the copper layer to prevent diffusion between the layers. The second negative characteristic is that copper readily forms a copper oxide when exposed to oxygen. The oxidation of copper becomes especially important on surfaces that are interfaces at which connections are made to other areas of the device, such as the surfaces of vias or trenches that are exposed after CMP. The formation of copper oxides at the interface between metal layers can increase the resistance (e.g., copper interconnects) and reduce the reliability of the overall circuit in the formed device.

One solution is to selectively deposit a metal alloy on copper surfaces which provides an efficient barrier to copper diffusion, electromigration and oxidation. This appears most readily accomplished using an electroless plating process selective for copper relative to dielectric material. Cobalt-containing alloys, such as cobalt tungsten phosphide (CoWP), are materials established to meet many or all requirements and may be deposited by electroless deposition techniques, though copper generally does not satisfactorily catalyze or initiate deposition of these materials from standard electroless solutions. While deposition of cobalt-containing alloys may be easily initiated electrochemically (e.g., by applying a sufficiently negative potential), a continuous conductive surface over the substrate surface is required and not available following Cu—CMP processes.

An established approach to initiating electroless deposition on copper surfaces is to deposit a thin layer of a catalytic metal on the copper surfaces by displacement plating. However, deposition of the catalytic material may require multiple steps or use of catalytic colloid compounds. Catalytic colloid compounds may adhere to dielectric materials on the substrate surface and result in undesired, non-selective deposition of the capping alloy material. Non-selective deposition of metal alloy capping material may lead to surface contamination and eventual device failure from short circuits and other device irregularities.

A catalytic activation layer may be deposited between the conductive layer and the capping layer and is generally composed of a single, noble metal, such as a palladium or platinum. Palladium activation processes typically proceed by displacement plating, that is, the replacement or sacrifice of existing atoms (e.g., copper) on the upper surface of a material by a secondary element (e.g., palladium). The most common palladium activation approach uses palladium chloride in an acidic solution, such as hydrochloric acid. However, the use of palladium chloride solutions typically results in the formation of clusters of palladium atoms bridged by chlorine atoms. Palladium cluster formation leads to nucleation growth on materials that are not desired to be activated, such as dielectric materials. The selectivity of the subsequent capping layer deposition is deteriorated due to palladium cluster contamination of the dielectric material and ultimate failure of the device.

The use of palladium sulfate in sulfuric acid as an activator has been disclosed in the art. However, palladium clusters are also formed and inhibit the selectivity of the following capping layer deposition. Sulfur used within the activation solution is believed to bridge the palladium atoms in a similar way as chlorine to form the palladium clusters.

Therefore, there is a need for a method to activate a conductive layer of a semiconductor feature with palladium prior to capping the conductive layer with a cobalt alloy, as well as a need for a composition of a palladium activation solution.

### SUMMARY OF THE INVENTION

Embodiments of the invention generally provide an activation treatment to a conductive surface, such as copper, followed by deposition of a capping layer, such as a cobalt-containing alloy. The activation treatment forms a palladium activation layer on a desired conductive surface by selective, electroless deposition. The palladium activation layer provides a catalytic surface to nucleate the cobalt-containing alloy deposition. Embodiments of the invention further provide processes and compositions for palladium activation solutions. Generally, the palladium activation solution includes palladium nitrate and at least one acid, such as nitric acid and/or an organosulfonic acid, for example, methanesulfonic acid. The capping layers are generally deposited by a deposition process utilizing electroless deposition solutions containing a cobalt source and a reductant.

In one embodiment, a method for activating a metal layer prior to depositing a cobalt-containing capping layer is provided which includes exposing the metal layer to an electroless activation solution to deposit a palladium layer on the metal layer and depositing the cobalt-containing capping layer on the palladium layer. The electroless activation solution contains palladium nitrate at a concentration in a range from about 0.01 mM to about 1.0 mM, nitric acid at a concentration in a range from about 0.01 mM to about 3.0 mM and water.

In another embodiment, a method for activating a metal layer prior to depositing a cobalt-containing capping layer is provided which includes cleaning the metal layer with a pre-clean solution, exposing the metal layer to an electroless activation solution to deposit a palladium layer on the metal layer, and depositing the cobalt-containing capping layer on the palladium layer. The electroless activation solution contains palladium nitrate at a concentration in a range from about 0.01 mM to about 1.0 mM, methanesulfonic acid at a concentration in a range from about 0.01 mM to about 3.0 mM and water.

In another embodiment, a method for activating a metal layer prior to depositing a cobalt-containing capping layer is provided which includes exposing the metal layer to a sulfur-free, chlorine-free, electroless activation solution, depositing a palladium layer on the metal layer and depositing the cobalt containing capping layer on the palladium layer. The sulfur-free, chlorine-free, electroless activation solution contains palladium nitrate at a concentration in a range from about 0.01 mM to about 1.0 mM, an acid at a concentration in a range from about 0.01 mM to about 3.0 mM and water.

In another embodiment, a method for activating a metal layer prior to depositing a cobalt-containing capping layer is provided which includes exposing the metal layer to an electroless activation solution which contains palladium nitrate at a concentration in a range from about 0.01 mM to about 1.0 mM, an acid at a concentration in a range from about 0.01 mM to about 3.0 mM, water and a pH additive to maintain a pH value in a range from about 2.0 to about 4.0, depositing a palladium layer on the copper layer, and depositing the cobalt-containing capping layer on the palladium layer.

In one embodiment, a composition of an electroless deposition solution is provided which includes water, palladium nitrate at a concentration in a range from about 0.001 mM to about 2.0 mM, and methanesulfonic acid at a concentration in a range from about 0.01 mM to about 3.0 mM.

In another embodiment, a method for activating a metal layer and passivating a barrier layer prior to depositing a cobalt-containing capping layer is provided which includes exposing the metal layer and the barrier layer to an electroless activation solution that includes palladium nitrate and nitric acid to deposit a palladium layer on the metal layer and to form a metal oxide layer on the barrier layer and depositing the cobalt-containing capping layer on the palladium layer.

In another embodiment, a method for activating a metal layer prior to depositing a cobalt-containing capping layer is provided which includes forming an electroless activation solution by in-line mixing palladium nitrate, nitric acid and water, wherein the electroless activation solution includes palladium nitrate at a concentration in a range from about 0.01 mM to about 1.0 mM and nitric acid at a concentration in a range from about 0.01 mM to about 3.0 mM. The method further includes exposing the metal layer to the electroless activation solution to deposit a palladium layer on the metal layer and depositing the cobalt-containing capping layer on the palladium layer.

In another embodiment, a method for activating a metal layer prior to depositing a cobalt-containing capping layer is provided which includes forming an electroless activation solution by in-line mixing palladium nitrate, organosulfonic acid and water, wherein the electroless activation solution includes palladium nitrate at a concentration in a range from about 0.01 mM to about 1.0 mM and an organosulfonic acid at a concentration in a range from about 0.01 mM to about 3.0 mM. The method further includes exposing the metal layer to the electroless activation solution to deposit a palladium layer on the metal layer.

In another embodiment, a composition of an electroless deposition solution is provided which includes water, palladium nitrate at a concentration in a range from about 0.001 mM to about 2.0 mM, and an organosulfonic acid at a concentration in a range from about 0.01 mM to about 3.0 mM.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIGS. 1A-1C show a step-wise formation of an interconnect structure;

FIG. 2 is a flow chart illustrating a process to form an interconnect structure;

FIGS. 3A-3C show images of capping layers deposited on conductive layers activated by various palladium activation solutions; and

FIG. 4 shows images of capping layers deposited on conductive layers activated with palladium activation solutions of varying pH values.

### DETAILED DESCRIPTION OF THE PREFERRED EMBODIMENT

The words and phrases used herein should be given their ordinary and customary meaning in the art as understood by one skilled in the art unless otherwise further defined. Electroless deposition is broadly defined herein as deposition of a conductive material by a replacement reaction wherein ions in a solution replace metal atoms in a surface while the metal atoms are ionized into the solution. Electroless deposition is also broadly defined herein as deposition of a conductive material by ions in a bath over a catalytically active surface to deposit the conductive material by chemical reduction in the absence of an external electric current.

Embodiments of the invention generally provide an activation treatment that avoids corrosion or oxidation of a conductive surface, such as copper, that may occur on a substrate surface after a CMP process. The activation treatment forms a palladium activation layer on a desired conductive surface by selective, electroless deposition. Embodiments of the invention further provide processes to deposit a capping layer, such as a cobalt-containing alloy layer, on the activated conductive layer. The capping layers are generally deposited by an electroless deposition process utilizing electroless deposition solutions.

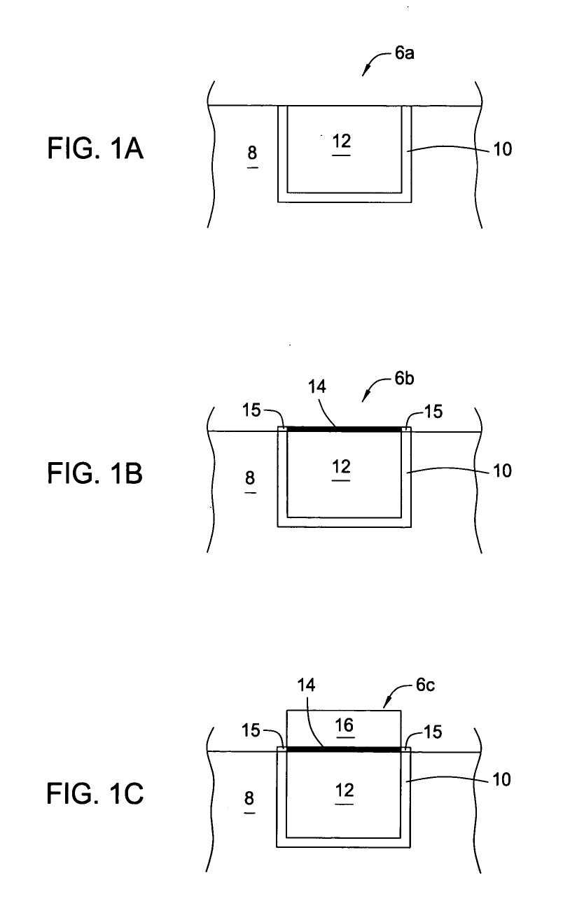

FIG. 1A shows a cross-sectional view of an interconnect 6a containing a conductive material 12 disposed into dielectric material 8, such as a low-k dielectric materials. Conductive material 12 is a metal, such as copper or copper alloys. The conductive material 12 is generally deposited by a deposition process, such as electroplating, electroless plating, chemical vapor deposition (CVD), atomic layer deposition (ALD), physical vapor deposition (PVD) and/or combinations thereof. As depicted in FIG. 1A, conductive material 12 may have already been polished or leveled, such as by a CMP technique. Dielectric material 8 may include features, such as plugs or interconnects, throughout the layer (not shown). A barrier layer 10 separates dielectric material 8 from the conductive material 12. Barrier layer 10 separates dielectric material 8 from the conductive material 12. Barrier layer 10 includes materials such as tantalum, tantalum nitride, titanium silicon nitride, tantalum silicon nitride, titanium, titanium nitride, tungsten nitride, silicon nitride and combinations thereof. In one embodiment, barrier layer 10 includes a tantalum layer deposited to a tantalum nitride layer. Barrier layer 10 is usually deposited with deposition processes, such as, PVD, ALD, CVD or combinations thereof.

Interconnect 6a, as well as other semiconductor features, are disposed on a substrate surface. Substrates on which embodiments of the invention may be useful include, but are not limited to semiconductor wafers, such as crystalline silicon (e.g., Si<100> or Si<111>), silicon on insulator substrate, silicon oxide, silicon germanium, doped or undoped polysilicon, doped or undoped silicon wafers, silicon nitride and patterned or non-patterned wafers. Surfaces may include bare silicon wafers, films, layers and materials with dielectric, conductive or barrier properties. Substrate surface is used herein to refer to any semiconductor feature present thereon, including the exposed surfaces of the features, such as the wall and/or bottom of vias, dual damascenes, contact holes and the like.

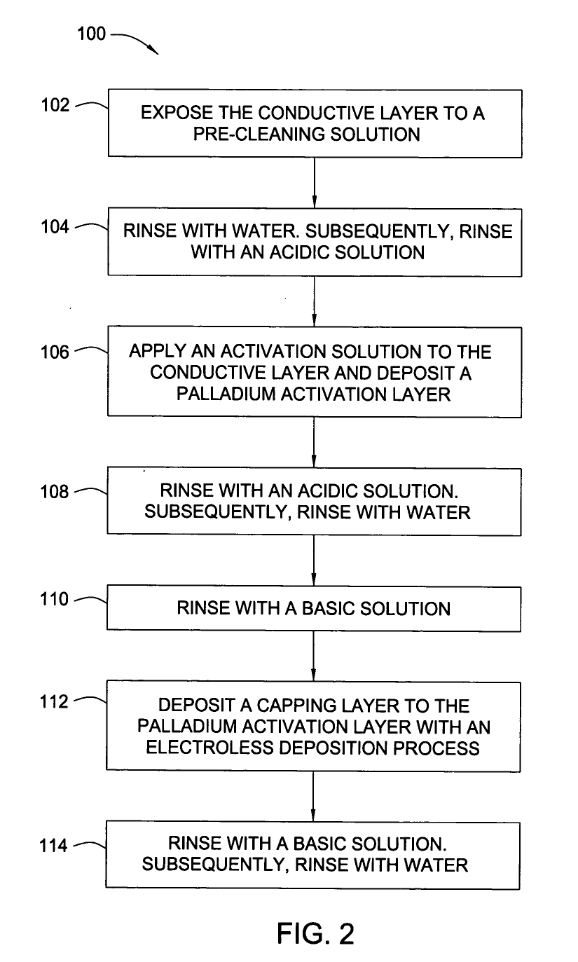

FIGS. 1A-1C depict cross-sectional views of interconnects 6a-6c resulting from steps taken during process 100. As shown in FIG. 2, a flow chart illustrates general steps taken during one embodiment of process 100. Process 100 includes step 102 to pre-clean the substrate surface, followed by step 104 to rinse the substrate with water and an acidic solution. During step 106, palladium activation layer 14 is deposited on conductive material 12. The substrate is exposed to an acidic solution rinse followed by a water rinse during step 108. During step 110, the substrate is exposed to a pH basic solution rinse. During step 112, capping layer 16, such as a cobalt-containing alloy, is deposited on palladium activation layer 14. Process 100 further includes step 114 with a pH basic solution rinse and a water rinse.

Prior to exposing the substrate to a pre-clean process, the substrate is initially wetted by, for example, exposing the substrate to degassed, deionized water. Generally, the substrate is rinsed for about 1 second to about 30 seconds, preferably for about 5 seconds to about 20 seconds, for example, about 10 seconds. During step 102, the substrate is exposed to a pre-clean process which includes exposing the substrate to a complexing agent solution to remove oxides, residues and/or contaminates remaining from a previous fabrication process (e.g., CMP). Contaminants include oxides, copper oxides, copper-organic complexes, silicon oxides, organic residues, resist, polymeric residues and combinations thereof. The pre-clean process exposes the surface to the complexing solution for about 5 seconds to about 120 seconds, preferably for about 10 seconds to about 30 seconds, and more preferably, for about 20 seconds. The complexing solution treats the exposed surface and removes contaminates from conductive material 12, any exposed barrier layer 10 and dielectric material 8.

The complexing agent solution is an aqueous solution containing a complexing agent, at least one acid, a pH adjusting agent and optional additives, such as a surfactant. The complexing agent may include compounds such as citric acid, EDTA, EDA, other carboxylic acids and amines, salts thereof, derivatives thereof and combinations thereof. The acids may include sulfuric acid, hydrochloric acid, hydrofluoric acid, phosphoric acid, methanesulfonic acid, derivatives thereof and combinations thereof. The pH adjusting agent may include tetramethylammonium hydroxide (TMAH), ammonia and other hydroxide or amine based compounds. Polyethylene glycol may be included as an additive to improve the wettability of the substrate surface by the complexing agent solution. The pre-clean process and the composition of the complexing solution are disclosed with more detail in commonly assigned U.S. Provisional Patent Application No. 60/536,958, entitled, “Wafer Cleaning Solution for Cobalt Electroless Application,” filed on Jan. 16, 2004, which is incorporated by reference herein to the extent not inconsistent with the claimed aspects and description herein.

In one embodiment, the complexing agent solution contains citric acid at a concentration in a range from about 0.05 M to about 1.0 M, EDTA at a concentration less than 1 vol %, sulfuric acid at a concentration in a range from about 0.05 N to about 1.0 N or hydrochloric acid at a concentration in a range from about 1 ppb to about 0.5 vol %, optional HF (49% aqueous solution) at a concentration in a range from about 10 ppm to about 2 vol %, and TMAH or ammonia in a concentration to adjust the pH to a range from about 1.5 to about 10.

Following exposure of the substrate to the complexing agent solution, the substrate surface is exposed to a rinse process during step 104. The rinse process includes exposing the substrate to degassed, deionized water and to an acidic solution rinse. Step 104 includes washing any remaining complexing solution and/or contaminants from the surface with degassed, deionized water. The substrate is rinsed with water for about 1 second to about 120 seconds, preferably for about 5 seconds to about 30 seconds.

Subsequent to the water rinse process, the substrate surface is exposed to an acidic solution rinse. The acidic solution rinse has a pH value in a range from about 1 to about 5, preferably from about 2 to about 3, for example, about 2.5. In one embodiment, the acidic solution rinse has a similar pH value as the activation solution that is employed during step 106. The acidic solution rinse contains degassed, deionized water and at least one acid, preferably, the acid may include methanesulfonic acid (CH₃SO₃H), nitric acid (HNO₃), phosphoric acid (H₃PO₄), hydrochloric acid (HCl), sulfuric acid (H₂SO₄), derivatives thereof and combinations thereof. The substrate is exposed to the acidic solution rinse for about 1 second to about 60 seconds, preferably for about 10 seconds to about 20 seconds. Optionally, the substrate is exposed to degassed, deionized water after the acidic solution rinse, prior to step 106.

During step 106, the substrate is exposed to an activation solution to form a palladium activation layer 14 on conductive material 12, as depicted in FIG. 1B. The exposure time of the activation solution to the substrate will range from about 1 second to about 120 seconds, preferably from about 20 seconds to about 60 seconds, and more preferably about 40 seconds. The palladium activation layer 14 may be a continuous layer or a discontinuous layer, such as satellites, across the surface of conductive material 12. In either variety, a continuous layer or a discontinuous layer, palladium activation layer 14 promotes nucleation during the deposition of capping layer 16. The palladium activation layer 14 may have a thickness from about a single atomic layer to about 50 Å, preferably from about 3 Å to about 20 Å. The palladium activation layer 14 is selectively deposited on conductive material 12 and not on the dielectric material 8. Dielectric material 8 may be contaminated with trace amounts of palladium clusters. However, this palladium contamination of the dielectric material 8 may be minimized by adjusting the concentration and pH of the activation solution.

The palladium activation layer 14 contains palladium or palladium alloys and is an active surface on which a subsequent capping layer may be deposited. The palladium activation layer 14 is deposited by a selective, displacement plating process using an activation solution. An activation solution used for displacement deposition is an aqueous solution that includes palladium nitrate (Pd(NO₃)₂) and at least one acid, such as nitric acid and/or an organosulfonic acid, such as methanesulfonic acid. A pH adjusting additive may be added to adjust the pH value of the activation solution. A pH adjusting additive to increase the pH value includes tetramethylammonium hydroxide (TMAH, (CH₃)₄NOH), ammonium hydroxide (NH₄OH), other hydroxides, ammonium or amine derivatives, and combinations thereof. A pH adjusting additive to decrease the pH value includes additional acid, such as nitric acid or an organosulfonic acid.

The activation solution may have palladium nitrate at a concentration in a range from about 0.001 mM to about 2.0 mM, preferably from about 0.01 mM to about 1.0 mM. In one example, palladium nitrate has a concentration of about 0.04 mM in the activation solution. In another example, palladium nitrate has a concentration of about 0.87 mM in the activation solution. The palladium nitrate concentration is proportional to the concentration of dissolved palladium ions within the activation solution. The activation solution may have an acid concentration in a range from about 0.01 mM to about 3.0 mM, preferably from about 0.1 mM to about 2.0 mM. The activation solution has an acidic pH value, preferably less than about 5, and more preferably about 4 or less. In one embodiment, an activation solution with a pH value from about 2.0 to about 4.0 provides a high degree of selectivity for depositing palladium onto conductive layers while not depositing palladium onto dielectric materials.

In one embodiment, a palladium activation solution concentrate may be formed by adding a 10 wt % solution of Pd(NO₃)₂ in water to 10 wt % nitric acid. The concentrated solution may be diluted from about 500 to about 10,000 times with degassed, deionized water to form the palladium activation solution. The pH value may be adjusted in a range of about 2.0 to about 4.0 with the addition of nitric acid or TMAH. In another embodiment, a solid palladium nitrate is first dissolved in degassed, deionized water to form a palladium nitrate solution. Solid palladium nitrate sources for use in the activation solution include Pd(NO₃)₂, Pd(H₂O)₂(NO₃)₂, Pd(NH₃)₄(NO₃)₂, Pd(THF)ₓ(NO₃)₂, Pd(Et₂O)ₓ(NO₃)₂, complexes thereof, derivatives thereof and combinations thereof.

In one embodiment, activation solutions containing palladium nitrate and nitric acid are very effective at passivating exposed barrier layer 10, such as tantalum and/or tantalum nitride. Nitric acid, unlike sulfuric acid or hydrochloric acid, is a strong oxidizer. The nitric acid forms passivation layer 15 on the portion of exposed barrier layer 10. The passivation layer may comprise tantalum oxide or tantalum oxynitride when barrier layer 10 is tantalum or tantalum nitride. Depending on the composition of barrier layer 10, other passivation layers may be formed by nitric acid exposure, such as titanium oxynitride, tantalum silicon oxynitride and titanium silicon oxynitride.

Sulfuric acid or hydrochloric acid may form sulfides or chlorides and contaminate multiple layers of the electronic device. Therefore, in one embodiment, sulfur-free and/or chlorine-free activation solutions are preferred. In another embodiment, an organosulfonic acid is used with palladium sources in an activation solution. Organosulfonic acids, such as alkylsulfonic acids and arylsulfonic acids, may provide some surfactant characteristics. For example, alkylsulfonic acids include smaller alkyl groups, such as methanesulfonic acid, ethanesulfonic acid, propanesulfonic acid, butanesulfonic acid as well as higher alkyl groups, such as nonanesulfonic acid, decanesulfonic acid, dodecanesulfonic acid and octadecanesulfonic acid. Arylsulfonic acids include benzenesulfonic acid, toluenesulfonic acid and naphthalenesulfonic acid. Organosulfonic acids work as a pH buffer while forming in situ nitric acid with palladium nitrate. For example, an organosulfonic acid, such as methanesulfonic acid, may be added to the palladium activation solution instead of nitric acid or in combination with nitric acid. In some formulations, nitric acid may oxidize the copper layer and cause copper erosion. Activation solutions containing an organosulfonic acid and palladium nitrate have been found to reduce the copper erosion compared to an activation solution with the same pH prepared using nitric acid and palladium nitrate.

During step 108, the palladium activation layer 14 is exposed to a post-clean solution, such as an acidic solution rinse. The acidic solution rinse may have a pH value from about 1 to about 5, preferably from about 2 to about 3, for example, about 2.5. In one embodiment, the acidic solution rinse has a similar pH value as the activation solution that is employed in step 106. The acidic solution rinse contains degassed, deionized water and at least one acid, preferably, the acid may include methanesulfonic acid, nitric acid, phosphoric acid, hydrochloric acid, sulfuric acid, salts thereof, derivatives thereof and combinations thereof. The substrate is exposed to the acidic solution rinse for about 1 second to about 60 seconds, preferably for about 10 seconds to about 20 seconds.

The acidic solution rinse may further contain at least one complexing agent to further clean the substrate surface and remove remaining contaminants left on the surface from prior process steps. Complexing agents are useful to reduce contaminates by chelating metal ions, such as copper or palladium. The complexing agent may include compounds such as citric acid, EDTA, EDA, other carboxylic acids and amines, salts thereof, derivatives thereof and combinations thereof.

Following exposure of the substrate to the acidic solution rinse, the substrate surface is exposed to a water rinse. The rinse step includes washing any remaining acidic solution, complexed metals and/or contaminants from the surface with degassed, deionized water. The substrate is rinsed with water about 1 second to about 30 seconds, preferably for about 5 seconds to about 10 seconds.

During step 110, the palladium activation layer 14 is exposed to a pH basic solution rinse. The pH basic solution rinse solution may have a pH value in a range from about 7.5 to about 12, preferably from about 8 to about 10, and more preferably from about 8.5 to about 9.5. In one embodiment, the pH basic rinse solution has a similar pH as the cobalt-containing solution that is employed in step 112. The pH basic rinse solution contains degassed, deionized water and at least one base, preferably, the base may include TMAH, ammonium hydroxide, tetrahydrofuran, pyridine, other ammonium or amine derivatives, complexes thereof, derivatives thereof and combinations thereof. The substrate is exposed to the pH basic solution rinse for about 1 second to about 60 seconds, preferably for about 10 seconds to about 20 seconds. Optionally, the substrate is exposed to degassed, deionized water after the pH basic solution rinse and before step 112.

A capping alloy layer 16 is deposited on the palladium activation layer 14 by an electroless deposition process, as depicted in FIG. 1C. The capping alloy layer 16 is deposited during step 112 by exposing activation layer 14 to a cobalt-containing solution. The capping layer 16 may include a variety of alloys containing cobalt, tungsten, molybdenum, boron, phosphorus and combinations thereof. Examples of cobalt-containing capping layers include CoW, CoWB, CoP, CoWP, CoWBP, CoMo, CoMoB, CoMoP and CoMoBP, wherein each elemental ratio varies. Generally, CoW alloys have a composition in weight percent, such as a cobalt concentration in a range from about 85% to about 95%, preferably from about 88% to about 90%, a tungsten concentration in a range from about 1% to about 6%, preferably from about 2% to about 4%, a boron concentration in a range from about 0% to about 6%, preferably from about 3% to about 4% and a phosphorus concentration in a range from about 0% to about 12%, preferably from about 6% to about 8%. In one example, a CoWP alloy with a cobalt concentration from about 88% to about 90% is deposited on a palladium activation layer. In one embodiment, the CoWP layer is deposited with a thickness of about 70 Å on a palladium layer with a thickness of about 10 Å.

A cobalt-containing alloy layer has a varying degree of amorphousity dependant to the phosphorus and/or boron concentration. Generally, barrier properties (e.g., stop diffusion of copper or oxygen) increase as the layer becomes more amorphous. Boron is incorporated into a cobalt-containing alloy to add bond strength and density to the alloy. Phosphorus is incorporated into a cobalt-containing alloy to delay crystallization of the alloy. Therefore, each element, boron and phosphorus, has distinct attributes while simultaneously manipulating the barrier properties of a cobalt-containing alloy layer.

In step 112, a cobalt-containing solution is exposed to the activation layer 14 to deposit a capping layer 16. Generally, the substrate is exposed to a cobalt-containing solution for a period in the range of about 5 seconds to about 90 seconds, preferably, about 20 seconds to about 45 seconds. A capping layer 16 is deposited to a thickness of about 1,000 Å or less, preferably about 500 Å or less and more preferably about 200 Å or less. For example, a capping layer 16 may have a thickness from about 5 Å to about 200 Å, preferably about 60 Å. A cobalt-containing solution is usually maintained at a temperature in the range from about 50° C. to about 95° C. and has a pH value in the range from about 7 to about 11, preferably, from about 8 to about 10, and more preferably about 9.

A cobalt-containing solution is an aqueous solution for electroless deposition that may include a cobalt source, a tungsten or molybdenum source, complexing agent, a buffering compound, an optional phosphorus source, an optional boron source, a surfactant, an optional oxygen scavenger, a pH adjusting agent and water, preferably degassed and deionized.

Cobalt sources usually have a cobalt concentration within the cobalt-containing solution at a range from about 50 mM to about 250 mM. Cobalt sources may include cobalt chlorides (e.g., CoCl₂.6H₂O), cobalt sulfates (e.g., CoSO₄.7H₂O), other water soluble Co²⁺ sources, derivates thereof, hydrates thereof, complexes thereof and combinations thereof. In one embodiment, CoCl₂.6H₂O is added to the cobalt-containing solution at a concentration in the range from about 1 g/L to about 100 g/L, preferably from about 15 g/L to about 35 g/L. In another embodiment, CoSO₄.7H₂O is added to the cobalt-containing solution at a concentration in the range from about 1 g/L to about 100 g/L, preferably from about 15 g/L to about 35 g/L.

Tungsten sources usually have a tungsten concentration in the range from about 10 mM to about 100 mM within the cobalt-containing solution. Tungsten sources may include CaWO₄, (NH₄)₂WO₄, H₂WO₄, other WO₄²⁻ sources or combinations thereof. In one embodiment, (NH₄)₂WO₄ is added to the cobalt-containing solution at a concentration in the range from about 1 g/L to about 50 g/L, preferably from about 5 g/L to about 15 g/L.

There is at least one reductant in the cobalt-containing solution. The reductant usually has a concentration in a range of about 1 mM to about 100 mM within the cobalt-containing solution. The at least one reductant may include phosphorus-based and/or boron-based reductants and also provide a phosphorus source or a boron source within the capping layer. Phosphorus-based reductants include hypophosphorous acid (H₃PO₂), salts thereof (e.g., Na, K, NH₄ or N(CH₃)₄) and combinations thereof. Boron-based reductants include boric acid (H₃BO₃), dimethylamine borane complex ((CH₃)₂NH.BH₃), DMAB), trimethylamine borane complex ((CH₃)₃N.BH₃), TMAB), tert-butylamine borane complex (^{t}BuNH₂.BH₃), tetrahydrofuran borane complex (THF.BH₃), pyridine borane complex (C₅H₅N.BH₃), ammonia borane complex (NH₃.BH₃), borane (BH₃), diborane (B₂H₆), derivatives thereof, complexes thereof and combinations thereof.

A complexing agent is also present in the cobalt-containing solution and may have a concentration in a range from about 10 mM to about 200 mM, preferably from about 30 mM to about 80 mM. In the cobalt-containing solution, complexing agents or chelators form complexes with cobalt sources (e.g., Co²⁺). Complexing agents may also provide buffering characteristics in the cobalt-containing solution. Complexing agents generally may have functional groups, such as amino acids, carboxylic acids, dicarboxylic acids, polycarboxylic acids, and amines, diamines and polyamines. Complexing agents may include citric acid, glycine, amino acids, ethylene diamine (EDA), ethylene diamine tetraacetic acid (EDTA), derivatives thereof, salts thereof and combinations thereof.

A surfactant is optionally added to the cobalt-containing solution in order to improve wettability of the palladium activation layer 14. The improved wettability of the palladium activation layer 14 improves film morphology and coverage of the palladium activation layer 14 during the deposition of the capping layer 16. The surfactant may have ionic or non-ionic characteristics. Glycol ether based surfactants (e.g., polyethylene glycol) may be used in the cobalt-containing solution, for example, surfactant containing polyoxyethylene units, such as TRITON® 100, available from Dow Chemical Company. Other useful surfactants may contain phosphate units, for example, sodium poly(oxyethylene) phenyl ether phosphate, such as RHODAFAC® RE-610, available from Rhodia, Inc. The surfactants may be homogeneous or a heterogeneous blend containing molecules of varying length hydrocarbon chains, for example, methyl, ethyl, propyl, and/or butyl. Surfactants usually have a concentration within the cobalt-containing solution of about 1.0 g/L or less, such as in a range from about 1 mg/L to about 100 mg/L, for example, about 25 mg/L.

An oxygen scavenger may also be included in the cobalt-containing solution to reduce or remove dissolved oxygen gas (O₂) from the solution. The lowered oxygen concentration in the cobalt-containing solution reduces copper corrosion and improves initiation delay for cobalt-containing alloy deposition. Oxygen may be removed from the cobalt-containing solution so that the oxygen concentration is less than 10 ppm, preferably, about 4 ppm or less. Oxygen scavengers include ascorbic acid, N,N-diethylhydroxylamine, erythorbic acid, methyl ethyl ketoxime, carbohydrazide, derivatives thereof and combinations thereof. The concentration of the oxygen scavenger within the cobalt-containing solution may be as low as about 10 ppm, but usually from about 0.01 mM to about 10 mM, preferably, from about 0.1 mM to about 5 mM. In a preferred embodiment, ascorbic acid is used as an oxygen scavenger in the cobalt-containing solution with the concentration from about 30 mg/L to about 300 mg/L, preferably about 100 mg/L.

The cobalt-containing solutions and deionized water may also be degassed to minimize dissolved oxygen. Degassing processes include treating the solution or water with membrane contactor systems, sonication, heating, bubbling inert gas (e.g., N₂ or Ar) through the water or plating solution. Membrane contactor systems include microporous, hollow fibers that are hydrophobic and are generally made from polypropylene. The fibers are selective to gas diffusion while not permitting liquids to pass. Oxygen is removed from the cobalt-containing plating solution and deionized water so that the oxygen concentration is less than 10 ppm, preferably about 4 ppm or less. The degassing processes may be used independently or in combination with the employment of oxygen scavengers. Also, degassed, deionized water is may be used while forming the cobalt-containing solution to insure a low oxygen concentration.

In one embodiment, a cobalt-containing solution includes a cobalt source, a tungsten source and an oxygen scavenger. In another embodiment, a cobalt-containing solution includes a cobalt source, a tungsten source, a phosphorus source and an oxygen scavenger. In another embodiment, a cobalt-containing solution includes a cobalt source, a tungsten source, a boron source and an oxygen scavenger. In another embodiment, a cobalt-containing solution includes a cobalt source, a tungsten source, a phosphorus source, a boron source and an oxygen scavenger. Each of the aforementioned embodiments may contain a surfactant within the cobalt-containing solution.

In one embodiment, a cobalt-containing solution used for the electroless deposition of a capping-layer contains a cobalt source at a concentration in a range of about 50 mM to about 250 mM, a tungsten source at a concentration in a range of about 10 mM to about 100 mM, a complexing agent at a concentration in a range of about 10 mM to about 200 mM, at least one reductant at a concentration in a range of about 1 mM to about 100 mM, a surfactant at a concentration in a range of about 1 mg/L to about 100 mg/L, and an oxygen scavenger at a concentration in a range of about 0.01 mM to about 10 mM. Preferably, the oxygen scavenger is ascorbic acid at a concentration in a range of about 30 mg/L to about 300 mg/L.

The processes described herein may be performed in an apparatus suitable for performing an electroless deposition process (EDP). A suitable apparatus includes the SLIMCELL™ processing platform that is available from Applied Materials, Inc., located in Santa Clara, Calif. The SLIMCELL™ platform, for example, includes an integrated processing chamber capable of depositing a conductive material by an electroless process, such as an EDP cell, which is available from Applied Materials, Inc., located in Santa Clara, Calif. The SLIMCELL™ platform generally includes one or more EDP cells as well as one or more pre-deposition or post-deposition cell, such as spin-rinse-dry (SRD) cells, etch chambers, or annealing chambers. A further description of EDP platforms and EDP cells may be found in the commonly assigned U.S. Provisional Patent Application Ser. No. 60/511,236, entitled, “Apparatus for Electroless Deposition,” filed on Oct. 15, 2003, U.S. patent application Ser. No. unknown, entitled, “Apparatus for Electroless Deposition,” filed on Oct. 15, 2004, U.S. Provisional Patent Application Ser. No. 60/539,491, entitled, “Apparatus for Electroless Deposition of Metals on Semiconductor Wafers,” filed on Jan. 26, 2004, U.S. Provisional Patent Application Ser. No. 60/575,553, entitled, “Face Up Electroless Plating Cell,” filed on May 28, 2004, and U.S. Provisional Patent Application Ser. No. 60/575,558, entitled, “Face Down Electroless Plating Cell,” filed on May 28, 2004, which are each incorporated by reference to the extent not inconsistent with the claimed aspects and description herein.

In one embodiment, the substrate is maintained at a predetermined temperature by being in thermal contact with a heating device, such as an electric heater or heated fluid passed on the backside of the substrate. The substrate is usually maintained at a temperature less than 100° C., such in a range from about 35° C. to about 95° C., for example, about 85° C. The process solutions, such as the cobalt-containing solution and/or the palladium activation solution, may be kept at room temperature (e.g., about 20° C.) or heated to a temperature not too great to cause the solutions to decompose, such as in a range from about 70° C. to about 85° C., for example, about 75° C.

The process chamber is usually purged with an inert gas in order to reduce the oxygen concentration from the process solutions, including the cobalt-containing solution, the palladium activation solution and the rinses. In one embodiment, after purging the process chamber, the humidity concentration within the process chamber is increased to reduce the evaporation of water from the process solutions on top of the substrate during a deposition process. Further disclosure regarding controlling humidity may be found in assigned, U.S. Provisional Patent Application Ser. No. 60/575,553, entitled, “Face-up Electroless Plating Cell,” filed on May 28, 2004, which is incorporated by reference herein to the extent not inconsistent with the claimed aspects and description herein. Also, throughout process 100, the dispense nozzle or other chemical delivery means may be swept across the substrate surface in order evenly distribute the solution. That is, during the administration of the pre-clean solution, rinse solutions (water, acidic or basic), palladium activation solution and/or cobalt-containing solution in steps 102-114, the nozzle is swept from one side, through the middle and to the opposite side of the substrate.

In embodiments of the invention, palladium activation solutions may be formed by combining solutions, such as palladium nitrate solutions, acids (e.g., nitric acid and/or organosulfonic acid), pH adjusting additives (e.g., TMAH or ammonium hydroxide) and/or water in various ratios. The mixing process used to form the solutions having the various ratios includes tank mixing, in-line mixing and/or combinations thereof. In some embodiments, solutions with a low concentration of palladium nitrate (mM) and a pH value in a range of about 2.0 to about 4.0 may cause palladium compounds to precipitate from the activation solution over the course of time (e.g., days). Therefore, in-line mixing of the activation solution, especially in-line diluting of the activation solution, ensures consistent composition concentration. In one example, a solution of palladium nitrate and nitric acid is in-line mixed with degassed, deionized water to form the activation solution. In another example, a concentrated palladium nitrate solution is in-line mixed with dilute nitric acid to form the activation solution. In another example, a palladium nitrate solution, nitric acid and degassed, deionized water are all in-line mixed to form the activation solution. Each of these aforementioned examples may include an organosulfonic acid along with or instead of the nitric acid. The substrate may be exposed to the palladium activation solution immediately after the in-line mixing. Preferably, the palladium activation solution is mixed in small quantities (e.g., about 1 L to about 2 L), held in a buffer vessel and immediately dispersed to the substrate surfaces.

The use of aliquots, or smaller volumetric quantities, has many advantageous over traditional electroless baths, including dilute solutions (i.e., concentrations in the mM instead of M), longer stability of an activation solution concentrate, more consistently deposited layers per substrate and less hazardous waste. The concentrations of the individual components in the activation solution are dilute in comparison to more traditional solutions. Traditional bath solutions for electroless deposition processes rely on higher concentrations of each component so that individual substrates within substrate batch have a relatively consistent exposure to each activation component within a bath. Some embodiments of this invention provide processes to expose the substrates to small volumetric aliquots of the palladium activation solution. Therefore, each substrate within a substrate batch is exposed to an activation solution with a consistent concentration.

During step 114, the capping layer 16 is exposed to a pH basic solution rinse. The pH basic solution rinse solution may have a pH value from about 7.5 to about 12, preferably from about 8 to about 10, and more preferably from about 8.5 to about 9.5. In one embodiment, the pH basic rinse solution has a similar pH value as the cobalt-containing solution that is employed in step 112. The pH basic rinse solution contains degassed, deionized water and at least one base, preferably, the base may include TMAH, ammonium hydroxide, tetrahydrofuran, pyridine, other ammonium or amine derivatives, complexes thereof, derivatives thereof and combinations thereof. The substrate is exposed to the pH basic solution rinse for about 1 second to about 60 seconds, preferably for about 10 seconds to about 20 seconds.

The pH basic rinse solution may further contain a complexing agent. The basic rinse solution containing a complexing agent further cleans the substrate surface and removes remaining contaminants from any of the early processes. Complexing agents are useful to chelate with metal ions, such as copper, palladium, cobalt or tungsten. The complexing agent may include compounds such as citric acid, EDTA, EDA, other carboxylic acids and amine, salts thereof, derivatives thereof and combinations thereof.

Following exposure of the substrate to the pH basic solution rinse, the substrate surface is rinsed with water. The rinse step includes washing any remaining basic solution, complexed metals and/or contaminants from the surface with degassed, deionized water. The substrate will be rinsed with water for about 5 seconds to about 120 seconds, preferably about 30 seconds.

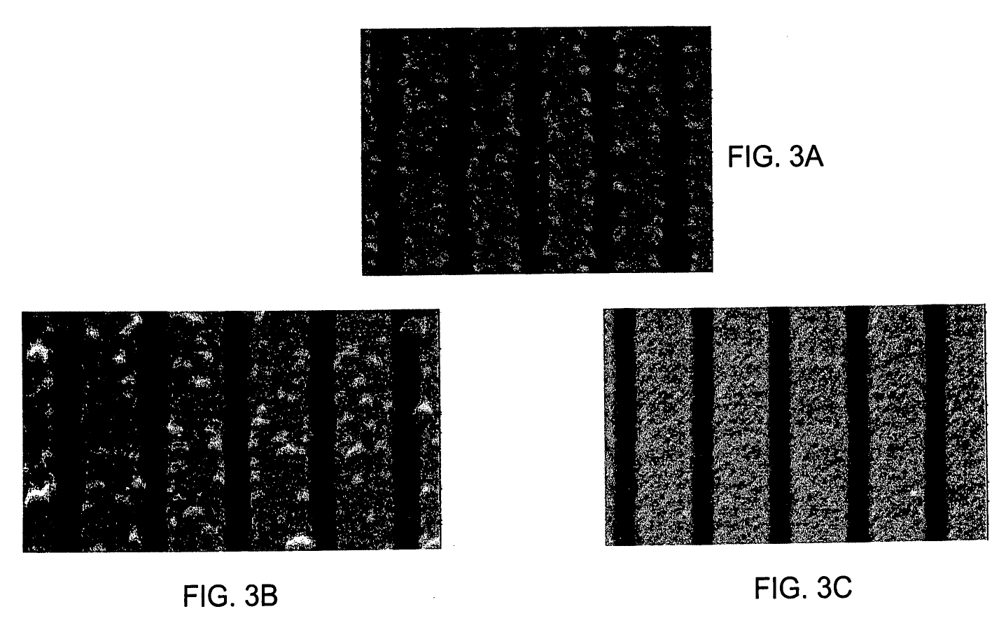

FIGS. 3A-3C are images from a scanning electron microscope (SEM) taken of cobalt-containing films deposited to palladium activated copper features supported on low-k material. The copper film activated with a palladium chloride solution is shown in FIG. 3A and copper film activated with a palladium sulfate solution is shown in FIG. 3B. After the palladium activation layer was deposited, cobalt-containing capping layers were deposited for 60 seconds at 75° C. Although the film depicted in FIG. 3B has larger clustered material than does the film depicted in FIG. 3A, both films are heavily contaminated with cobalt-containing material across the low-k material. The cobalt-containing contaminate is formed on palladium clusters adhered to the low-k material.

FIG. 3C illustrates a copper film activated with palladium nitrate solution, as described in the invention, prior to depositing a cobalt-containing capping layer to the activated palladium layer. The cobalt-containing layer was deposited with the same deposition solution and conditions as the cobalt-containing layers depicted in FIGS. 3A-3B. FIG. 3C reveals no cobalt-containing contamination on the low-k dielectric material. It is believed that the palladium nitrate activation solution does not form palladium clusters, therefore inhibits the production of cobalt-containing contaminates on the low-k material.

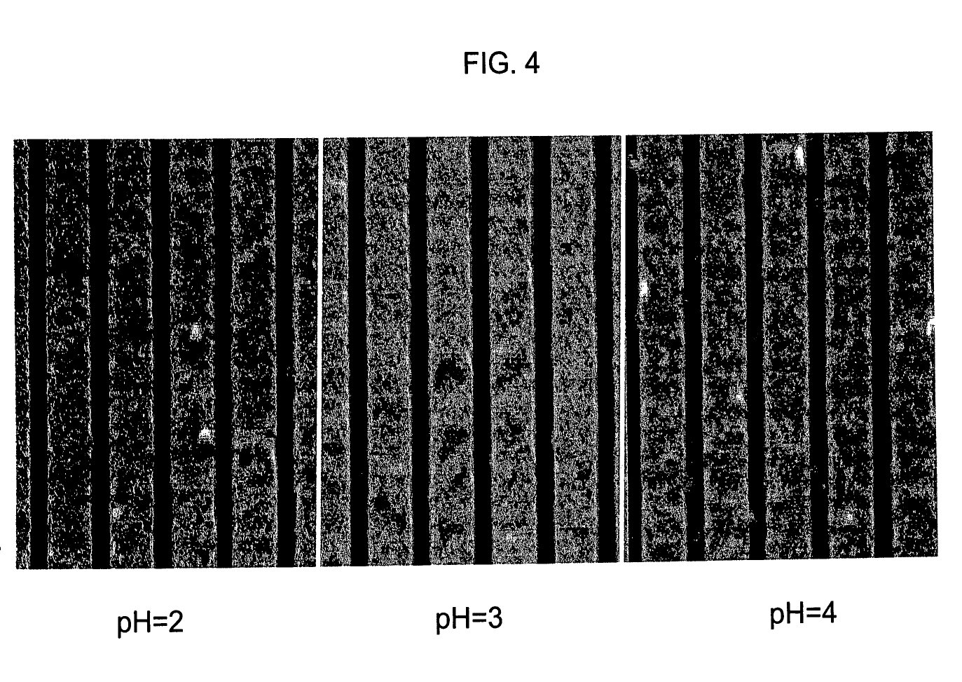

FIG. 4 depicts SEM images of several cobalt-containing films wherein the underlying copper film was activated with palladium nitrate activation solutions at varying pH. Trace amounts of cobalt-containing contaminate are formed on palladium clusters adhered to the low-k dielectric when the underlying copper layer is activated at a pH of about 2. A surprising and unexpected result showed no visible cobalt-containing contaminates are formed on palladium clusters adhered to the low-k dielectric when the underlying copper layer is activated at a pH of about 3. However, more noticeable cobalt-containing contaminates are formed on palladium clusters adhered to the low-k dielectric when the underlying copper layer is activated at a pH of about 4. Therefore, in one embodiment, an activation solution with a pH value from about 2.0 to about 4.0 has a preferred acidity.

### HYPOTHETICAL EXAMPLES

### Example 1

After a CMP process, a 300 mm substrate containing copper filled features supported by TaN/Ta barrier layers was rinsed with degassed, deionized water, exposed to a complexing solution for 30 seconds and subsequently rinsed with degassed, deionized water for 30 seconds. The substrate was exposed to an acidic wash containing HNO₃ with a pH of 2.8. The acidified substrate was exposed for 60 seconds to 200 mL of a palladium activation solution (pH of 2.8) containing 0.04 mM Pd(NO₃)₂ and 1.0 mM HNO₃. The substrate was rinsed with the acid wash and subsequently rinsed with degassed, deionized water for 30 seconds. The rinsed substrate was exposed to a pH basic wash solution containing TMAH for 20 seconds. The basified palladium layer was exposed to an electroless cobalt-containing solution containing 25 mg/L of surfactant (TRITON® 100) and 100 mg/L of ascorbic acid to form a capping layer. The substrate was rinsed with the pH basic wash solution and subsequent degassed, deionized water. The CoWP capping layer was deposited on the palladium activated copper features, but no detectable CoWP was detected on the low-k material.

### Example 2

After a CMP process, a 300 mm substrate containing copper filled features supported by TaN/Ta barrier layers was rinsed with degassed, deionized water, exposed to a complexing solution for 30 seconds and subsequently rinsed with degassed, deionized water for 30 seconds. The substrate was exposed to an acidic wash containing HNO₃ with a pH of 2.5. The acidified substrate was exposed for 40 seconds to 200 mL of a palladium activation solution (pH of 2.5) containing 0.87 mM Pd(NO₃)₂ and 2.0 mM HNO₃. The substrate was rinsed with the acid wash and subsequently rinsed with degassed, deionized water for 30 seconds. The rinsed substrate was exposed to a pH basic wash solution containing TMAH for 20 seconds. The basified palladium layer was exposed to an electroless cobalt-containing solution containing 25 mg/L of surfactant (TRITON® 100) and 100 mg/L of ascorbic acid to form a capping layer. The substrate was rinsed with the pH basic wash solution and subsequent degassed, deionized water. The CoWP capping layer was deposited on the palladium activated copper features, but no detectable CoWP was detected on the low-k material.

### Example 3

After a CMP process, a 300 mm substrate containing copper filled features supported by TaN/Ta barrier layers was rinsed with degassed, deionized water, exposed to a complexing solution for 30 seconds and subsequently rinsed with degassed, deionized water for 30 seconds. The substrate was exposed to an acidic wash containing HNO₃ with a pH of 2.9. The acidified substrate was exposed for 60 seconds to 200 mL of a palladium activation solution (pH of 2.9) containing 0.04 mM Pd(NO₃)₂ and 1.0 mM methanesulfonic acid. The substrate was rinsed with the acid wash and subsequently rinsed with degassed, deionized water for 30 seconds. The rinsed substrate was exposed to a pH basic wash solution containing TMAH for 20 seconds. The basified palladium layer was exposed to an electroless cobalt-containing solution containing 25 mg/L of surfactant (TRITON® 100) and 100 mg/L of ascorbic acid to form a capping layer. The substrate was rinsed with the pH basic wash solution and subsequent degassed, deionized water. The CoWP capping layer was deposited on the palladium activated copper features, but no detectable CoWP was detected on the low-k material.

### Example 4

After a CMP process, a 300 mm substrate containing copper filled features supported by TaN/Ta barrier layers was rinsed with degassed, deionized water, exposed to a complexing solution for 30 seconds and subsequently rinsed with degassed, deionized water for 30 seconds. The substrate was exposed to an acidic wash containing HNO₃ with a pH of 2.6. The acidified substrate was exposed for 40 seconds to 200 mL of a palladium activation solution (pH of 2.6) containing 0.87 mM Pd(NO₃)₂ and 2.0 mM and methanesulfonic acid. The substrate was rinsed with the acid wash and subsequently rinsed with degassed, deionized water for 30 seconds. The rinsed substrate was exposed to a pH basic wash solution containing TMAH for 20 seconds. The basified palladium layer was exposed to an electroless cobalt-containing solution containing 25 mg/L of surfactant (TRITON® 100) and 100 mg/L of ascorbic acid to form a capping layer. The substrate was rinsed with the pH basic wash solution and subsequent degassed, deionized water. The CoWP capping layer was deposited on the palladium activated copper features, but no detectable CoWP was detected on the low-k material.

While the foregoing is directed to embodiments of the present invention, other and further embodiments of the invention may be devised without departing from the basic scope thereof, and the scope thereof is determined by the claims that follow.

1. A method for activating a metal layer prior to depositing a cobalt-containing capping layer, comprising:
depositing a palladium layer on the metal layer by exposing the metal layer to an electroless activation solution comprising:
palladium nitrate at a concentration in a range from about 0.01 mM to about 1.0 mM; and
nitric acid at a concentration in a range from about 0.01 mM to about 3.0 mM; and
depositing the cobalt-containing capping layer on the palladium layer.

2. The method of claim 1, wherein the metal layer is copper or a copper alloy.

3. The method of claim 2, wherein the cobalt-containing capping layer comprises at least one element selected from the group consisting of tungsten, molybdenum, phosphorus, boron and combinations thereof.

4. The method of claim 3, wherein the cobalt-containing capping layer is selected from the group consisting of CoW, CoWP, CoP, CoWBP and combinations thereof.

5. The method of claim 2, wherein the electroless activation solution has a pH value of about 4 or less.

6. The method of claim 5, wherein the pH value is in a range from about 2.0 to about 4.0.

7. A method for activating a metal layer prior to depositing a cobalt-containing capping layer, comprising:
cleaning the metal layer with a pre-clean solution;
depositing a palladium layer on the metal layer by exposing the metal layer to an electroless activation solution comprising:
palladium nitrate at a concentration in a range from about 0.01 mM to about 1.0 mM; and
methanesulfonic acid at a concentration in a range from about 0.01 mM to about 3.0 mM; and
depositing the cobalt-containing capping layer on the palladium layer.

8. The method of claim 7, wherein the metal layer is copper or a copper alloy.

9. The method of claim 8, wherein the cobalt-containing capping layer comprises at least one element selected from the group consisting of tungsten, molybdenum, phosphorus, boron and combinations thereof.

10. The method of claim 9, wherein the cobalt-containing capping layer is selected from the group consisting of CoW, CoWP, CoP, CoWBP and combinations thereof.

11. The method of claim 8, wherein the electroless activation solution has a pH value of about 4 or less.

12. The method of claim 11, wherein the pH value is in a range from about 2.0 to about 4.0.

13. A method for activating a metal layer prior to depositing a cobalt-containing capping layer, comprising:
depositing a palladium layer on the copper layer by exposing the metal layer to a sulfur-free, chlorine-free, electroless activation solution comprising:
palladium nitrate at a concentration in a range from about 0.01 mM to about 1.0 mM; and
an acid at a concentration in a range from about 0.01 mM to about 3.0 mM; and
depositing the cobalt-containing capping layer on the palladium layer.

14. The method of claim 13, wherein the metal layer is copper or a copper alloy.

15. The method of claim 14, wherein the acid is nitric acid.

16. The method of claim 15, wherein the cobalt-containing capping layer comprises at least one element selected from the group consisting of tungsten, molybdenum, phosphorus, boron and combinations thereof.

17. The method of claim 14, wherein the sulfur-free, chlorine-free, electroless activation solution has a pH value of about 4 or less.

18. The method of claim 17, wherein the pH value is in a range from about 2.0 to about 4.0.

19. A method for activating a metal layer prior to depositing a cobalt-containing capping layer, comprising:
depositing a palladium layer on the metal layer by exposing the metal layer to an electroless activation solution comprising:
palladium nitrate at a concentration in a range from about 0.01 mM to about 1.0 mM;
an acid at a concentration in a range from about 0.01 mM to about 3.0 mM; and
a pH additive to maintain a pH value in a range from about 2.0 to about 4.0; and
depositing the cobalt-containing capping layer on the palladium layer.

20. The method of claim 19, wherein the metal layer is copper or a copper alloy.

21. The method of claim 20, wherein the acid is selected from the group consisting of nitric acid, organosulfonic acid, methanesulfonic acid and combinations thereof.

22. The method of claim 21, wherein the cobalt-containing capping layer comprises at least one element selected from the group consisting of tungsten, molybdenum, phosphorus, boron and combinations thereof.

23. The method of claim 19, wherein the pH additive is selected from the group consisting of tetramethylammonium hydroxide, ammonium hydroxide, derivatives thereof and combinations thereof.

24. A composition of an electroless deposition solution, comprising:
water;
palladium nitrate at a concentration in a range from about 0.001 mM to about 2.0 mM; and
methanesulfonic acid at a concentration in a range from about 0.01 mM to about 3.0 mM.

25. A method for activating a metal layer and passivating a barrier layer prior to depositing a cobalt-containing capping layer, comprising:
depositing a palladium layer on the metal layer and forming a metal oxide layer on the barrier layer by exposing the metal layer and the barrier layer to an electroless activation solution comprising palladium nitrate and nitric acid; and
depositing the cobalt-containing capping layer on the palladium layer.

26. The method of claim 25, wherein the metal layer is copper or a copper alloy.

27. The method of claim 26, wherein the palladium nitrate is within the electroless activation solution at a concentration in a range from about 0.01 mM to about 1.0 mM.

28. The method of claim 27, wherein the nitric acid is within the electroless activation solution at a concentration in a range from about 0.01 mM to about 3.0 mM.

29. The method of claim 28, wherein the electroless activation solution has a pH value of about 4 or less.

30. The method of claim 29, wherein the pH value is in a range from about 2.0 to about 4.0.

31. The method of claim 25, wherein the barrier layer is selected from the group consisting of tantalum, tantalum nitride, tantalum silicon nitride, titanium, titanium nitride, titanium silicon nitride, tungsten and combinations thereof.

32. The method of claim 31, wherein the metal oxide layer is selected from the group consisting of tantalum oxide, tantalum oxynitride, tantalum silicon oxynitride, titanium oxide, titanium oxynitride, titanium silicon oxynitride, tungsten oxide and combinations thereof.

33. A method for activating a metal layer prior to depositing a cobalt-containing capping layer, comprising:
forming an electroless activation solution by in-line mixing palladium nitrate, nitric acid and water, wherein the electroless activation solution contains the palladium nitrate at a concentration in a range from about 0.01 mM to about 1.0 mM and the nitric acid at a concentration in a range from about 0.01 mM to about 3.0 mM;
depositing a palladium layer on the metal layer by exposing the metal layer to the electroless activation solution; and
depositing the cobalt-containing capping layer on the palladium layer.

34. The method of claim 33, wherein the metal layer is copper or a copper alloy.

35. The method of claim 34, wherein the cobalt-containing capping layer comprises at least one element selected from the group consisting of tungsten, molybdenum, phosphorus, boron and combinations thereof.

36. The method of claim 35, wherein the cobalt-containing capping layer is selected from the group consisting of CoW, CoWP, CoP, CoWBP and combinations thereof.

37. The method of claim 34, wherein the electroless activation solution has a pH value of about 4 or less.

38. The method of claim 37, wherein the pH value is in a range from about 2.0 to about 4.0.

39. A method for activating a metal layer prior to depositing a cobalt-containing capping layer, comprising:
forming an electroless activation solution by in-line mixing palladium nitrate, organosulfonic acid and water, wherein the electroless activation solution contains the palladium nitrate at a concentration in a range from about 0.01 mM to about 1.0 mM and the organosulfonic acid at a concentration in a range from about 0.01 mM to about 3.0 mM; and
depositing a palladium layer on the metal layer by exposing the metal layer on the electroless activation solution.

40. The method of claim 39, wherein the metal layer is copper or a copper alloy.

41. The method of claim 40, wherein the cobalt-containing capping layer is deposited on the palladium layer.

42. The method of claim 41, wherein the cobalt-containing capping layer comprises at least one element selected from the group consisting of tungsten, molybdenum, phosphorus, boron and combinations thereof.

43. The method of claim 42, wherein the cobalt-containing capping layer is selected from the group consisting of CoW, CoWP, CoP, CoWBP and combinations thereof.

44. The method of claim 40, wherein the electroless activation solution has a pH value of about 4 or less.

45. The method of claim 44, wherein the pH value is in a range from about 2.0 to about 4.0.

46. The method of claim 45, wherein the organosulfonic acid is selected from the group consisting of methanesulfonic acid, decanesulfonic acid, benzenesulfonic acid and combinations thereof.

47. A composition of an electroless deposition solution, comprising:
water;
palladium nitrate at a concentration in a range from about 0.001 mM to about 2.0 mM; and
an organosulfonic acid at a concentration in a range from about 0.01 mM to about 3.0 mM.
